(19) United States
(12) Patent Application Publication
(10) Pub. No.: US 2004/0251799 A1
(43) Pub. Date: Dec. 16, 2004

(54) System for securing a component in a computer system

(75) Inventors: Walter A. Goodman, Raleigh, NC (US); Rodrigo Samper, Raleigh, NC (US)

Correspondence Address: SAWYER LAW GROUP LLP, PO BOX 51418, PALO ALTO, CA, 94303, US

(73) Assignee: International Business Machines Corporation, Armonk, NY

(21) Appl. No.: 10/460,132

(22) Filed: Jun. 12, 2003

(51) Int. Cl. H05K 7/18

(52) U.S. Cl. 312/223.2

(57) ABSTRACT

A system for securing a computer component in a cage of a computer system is disclosed. According to a preferred embodiment, the system comprises a retainer clip coupled to a surface of the computer component, wherein the retainer clip includes a leaf spring that engages the cage when the component is placed into the cage.

### FIELD OF THE INVENTION

The present invention relates generally to computer storage systems and, more particularly, to a tool-less system for securing a component in a computer system.

### BACKGROUND OF THE INVENTION

Computer components, such as floppy disk drives and optical devices, are generally stored in a cage or frame that provides openings (or bays) into which the components are inserted. FIG. 1 illustrates a typical cage 10 with a component 20 inserted into a 5.25″ bay 30. Generally, the component 20 is supported by rails (not shown) inside the cage 10 so that the component 20 slides into and out of the bay 30. As is shown, the cage 10 includes a plurality of holes 40 that correspond to screw holes (not shown) on a side surface of the component 20. Thus, when the component 20 is inserted completely into the cage 10, the component is secured to the cage 10 by screws (not shown) via the holes 40. As is shown, the cage also includes a 3.5″ bay 40 for a smaller component, e.g., a floppy disk drive (not shown).

The cage 10 usually fits into a larger housing that encloses other elements of a computer system, such as the system board. As computer systems decrease in size, the components that make up a system are more closely arranged, i.e., the packaging density increases. In certain circumstances, access to one component is impossible without removing, or at least moving, another component. For example, a component 20 housed in the cage 10 can block access to a system board. Thus, a technician or operator must remove or move the component 20 before he or she can replace or service system components.

As stated above, components 20 are generally screwed into the cage 10. Therefore, in order to remove or move a component 20, the technician must first unscrew the component 20. This process, while simple, is time consuming and cumbersome. Moreover, the technician must keep track of the screws.

Accordingly, there exists a need for a system that secures a component in a computer system and that also allows a technician to easily and quickly remove or move the component. The present invention addresses such a need.

### SUMMARY OF THE INVENTION

The present invention is directed to a system for securing a computer component in a cage of a computer system. According to a preferred embodiment, the system comprises a retainer clip coupled to a surface of the component, wherein the retainer clip includes a leaf spring that engages a cage when the component is placed into the cage.

Through the aspects of the present invention, the retainer clip preferably attaches to the component via a plurality of tabs on the retainer clip. Because the component is secured within the cage by the leaf spring, as opposed to screws, the technician can remove or move the component simply by releasing the leaf spring, i.e., by depressing the spring into the cage. This releases the component, making it free to slide within the cage. Thus, the technician can move the component easily and quickly and without utilizing tools.

### BRIEF DESCRIPTION OF THE DRAWINGS

FIG. 1 illustrates a conventional cage.

FIG. 2A illustrates a perspective front view of the retainer clip according to a preferred embodiment of the present invention.

FIG. 2B illustrates a perspective back view of the retainer clip according to a preferred embodiment of the present invention.

FIG. 3 illustrates a perspective view of the retainer clip according to another preferred embodiment of the present invention.

FIG. 4 illustrates the retainer clip attached to a side surface of the component according to the preferred embodiment of the present invention.

FIG. 5 illustrates a side view of a portion of the cage according to a preferred embodiment of the present invention.

FIGS. 6A and 6B illustrate how the retainer clip 50 is used in cooperation with the cage 70 to secure a component 20 in the cage 70.

FIGS. 7A and 7B illustrate two perspective views of the spring opening according to a preferred embodiment.

FIG. 8 illustrates the retainer clips viewed from inside the cage according to the preferred embodiment of the present invention.

FIG. 9 illustrates a housing for a component according to a preferred embodiment.

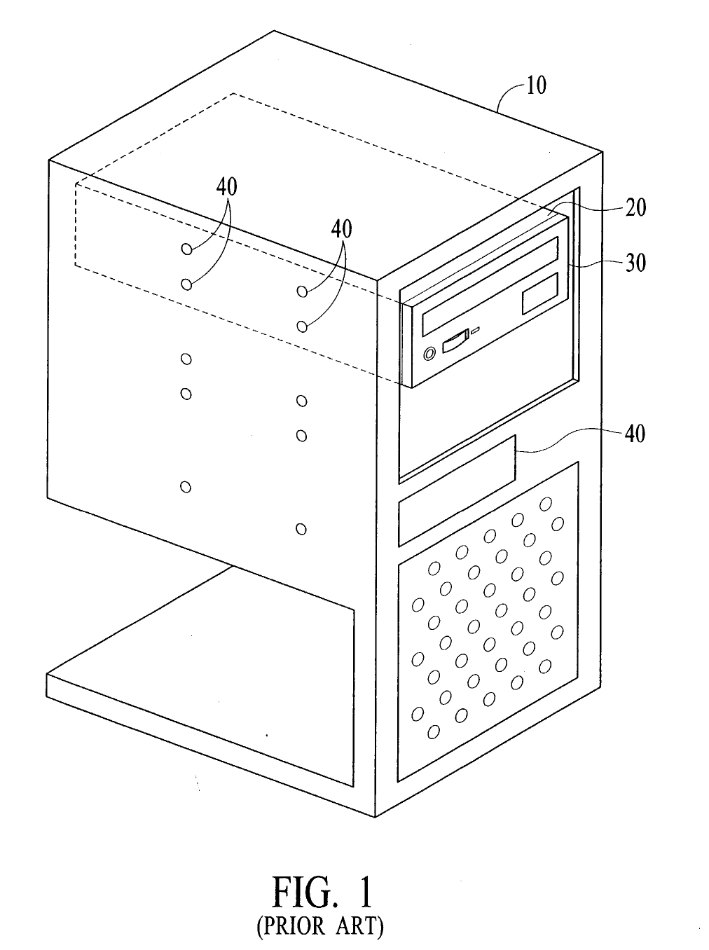

### DETAILED DESCRIPTION

The present invention relates generally to computer storage systems and, more particularly, to a tool-less system for securing a component in a computer system. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

In accordance with the present invention, the component is secured in the cage by a retainer clip that is coupled to a side surface of the component. The retainer clip includes a leaf spring, which is simply a sleeve that has one end fixed on the retainer clip and one free end that extends from the fixed end at an acute angle. The cage includes an opening for receiving the leaf spring so that when the component is inserted completely into the cage's bay, i.e., into a final position, the leaf spring snaps into the opening and prevents the component from being displaced. When the component needs to be moved, the technician depresses the leaf spring such that it slips beneath the inside surface of the cage, and slides the component out of the cage.

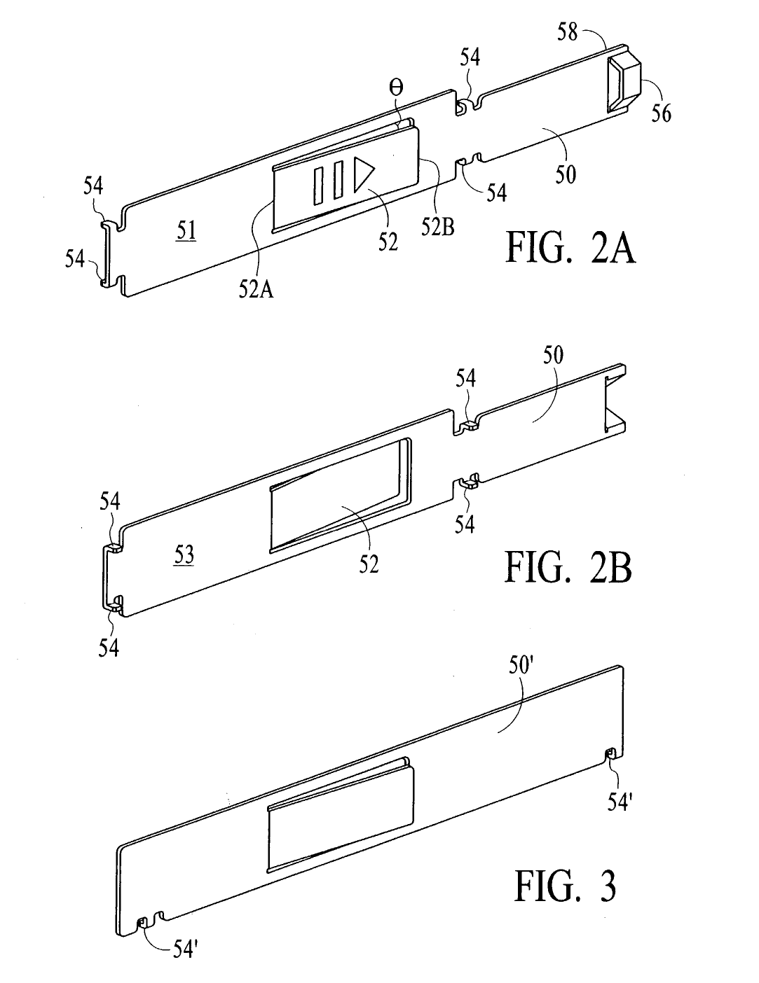

To describe in more detail the particular features of the present invention, please refer to FIGS. 2A and 2B, which are perspective front and back views, respectively, of a retainer clip according to a preferred embodiment of the present invention. Similar elements are identified by similar item numbers. As is shown, the retainer clip 50 is a single piece of material, preferably sheet metal, that is thin and elongated with a formed leaf spring 52. The leaf spring 52 is an integral part of the retainer clip 50, and is a sleeve that is fixed at one end 52A and free at another end 52B. The free end 52B is closest to a front edge 58 of the retainer clip 50. The leaf spring 52 extends outward from an outer surface 51 of the retainer clip 50 at an acute angle, θ, in its natural position, i.e., when no pressure is exerted on the leaf spring 52.

The retainer clip 50 also includes a plurality of tabs 54 that bend inward from an inner surface 53 of the retainer clip 50. The tabs 54 are substantially perpendicular to the inner surface 53 of the retainer clip 50, and are utilized to secure the retainer clip 50 to the component (not shown) via the component's screw holes. In a preferred embodiment, the tabs 54 are bent slightly off perpendicular so that when they are inserted into the component's screw holes, the tabs 54 tightly secure the clip 50 to the component 20.

A person skilled in the art would appreciate that the number and positioning of the tabs 54 can vary and is dependent, in part, on the particular component 20. For example, the retainer clip 50 illustrated in FIGS. 2A and 2B is configured to support a 5.25″ device and includes four tabs 54, positioned opposite to one another. For smaller components, such as a 3.5″ floppy disk drive, the retainer clip 50′ illustrated in FIG. 3 may be more suitable. Here, the retainer clip 50′ supports the smaller component with two tabs 54′, which correspond to two screw holes (not shown) in the component. Such a design variation would fall within the scope of the present invention.

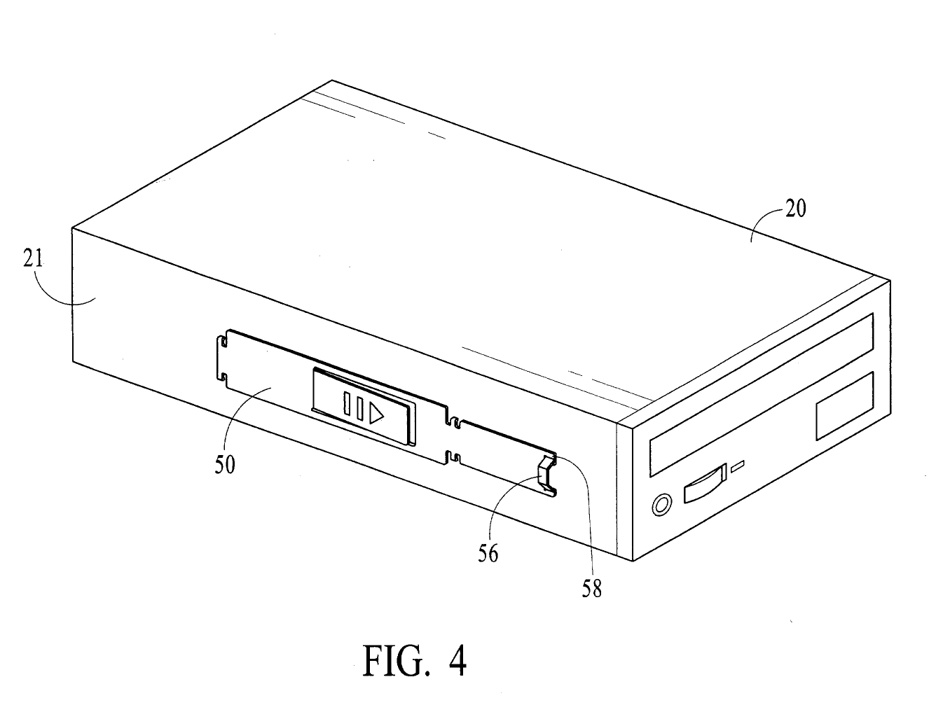

FIG. 4 illustrates the retainer clip 50 attached to a side surface 21 of the component 20 according to the preferred embodiment of the present invention.

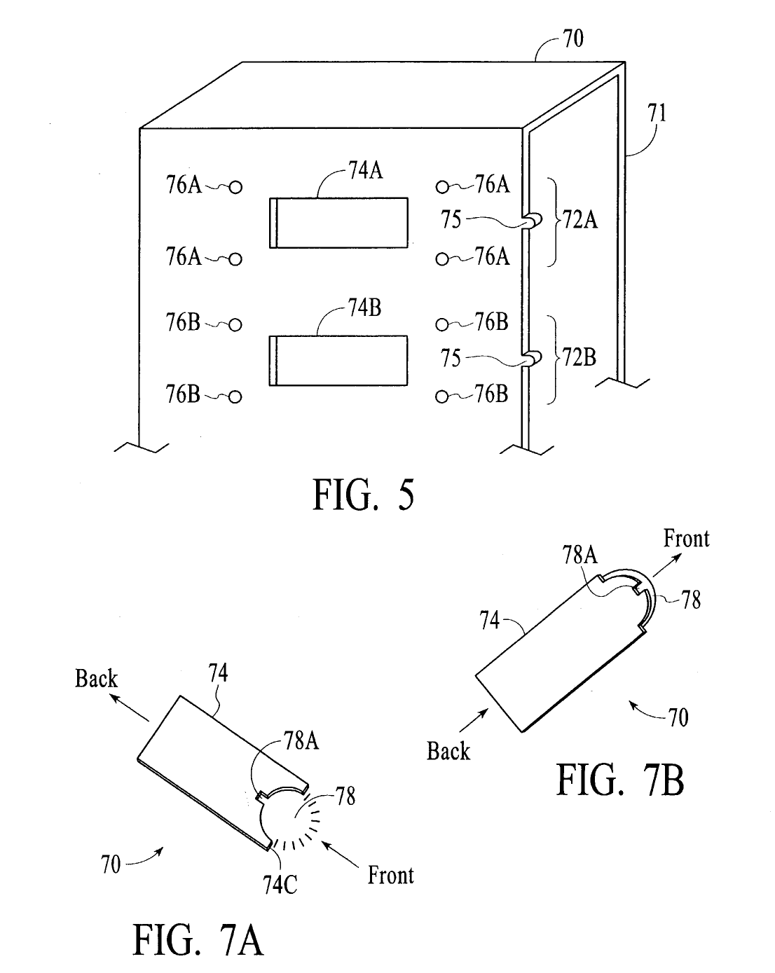

Referring now to FIG. 5, a side view of a portion of the cage according to a preferred embodiment of the present invention is illustrated. For each bay 72A, 72B, the cage 70 includes a spring opening 74A, 74B and a corresponding set of through holes 76A, 76B. The spring opening 74A is configured to receive the leaf spring 52 (FIGS. 2-4) when the component 20 is inserted completely into the cage 70, i.e., when the component 20 is in the final position. In the final position, the through holes 76A, 76B are aligned with the screw holes in the component 20.

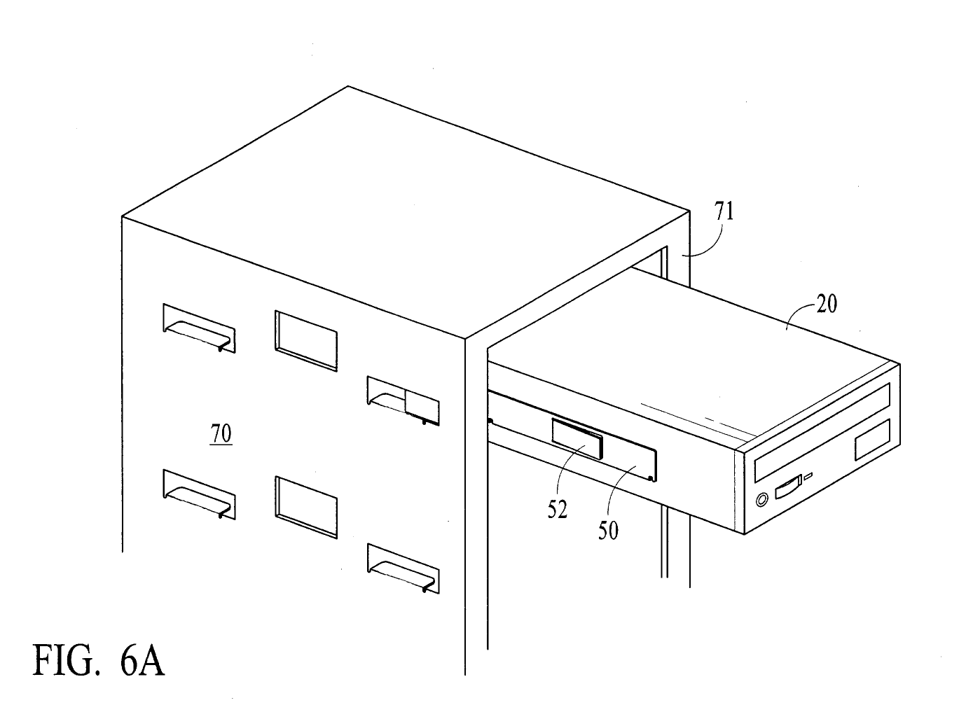

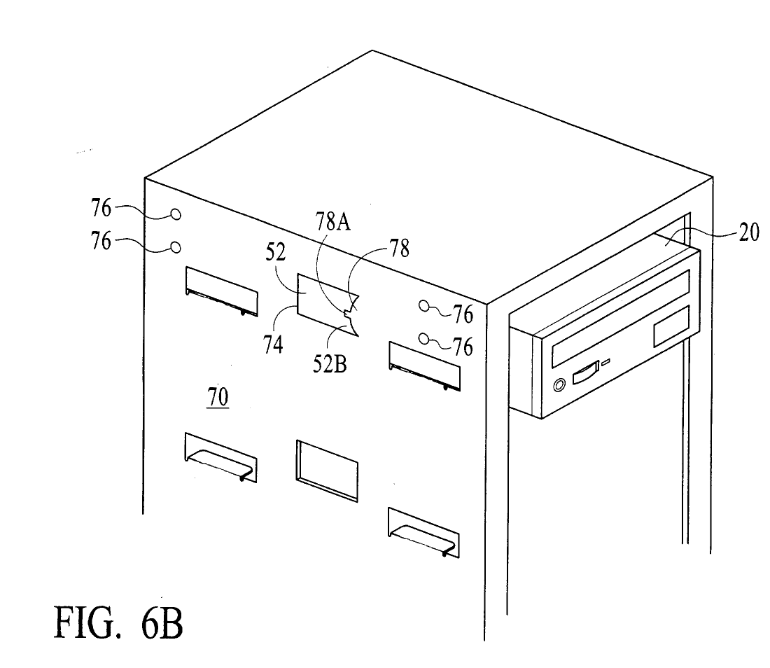

FIGS. 6A and 6B illustrate how the retainer clip 50 is used in cooperation with the cage 70 to secure a component 20 in the cage 70. FIG. 6A shows the retainer clip 50 coupled to the component 20 and shows the component 20 in a first position as it is being inserted into the cage 70. FIG. 6B shows the component 20 in the final secured position within the cage 70. As FIG. 6A shows, the component 20 is inserted into the front face 71 of the cage 70.

As the component 20 slides into the cage 70, the leaf spring 52 eventually comes in contact with the cage 70 and naturally bends inward (contracts) because of its orientation, thereby allowing the component 20 to be inserted into the cage 70. When the component 20 reaches the final position, as shown in FIG. 6B, the leaf spring 52 fits into the spring opening 74 and the free end 52B of the leaf spring 42 retracts into the spring opening 74.

Referring now to FIGS. 7A and 7B, which illustrate two perspectives of the spring opening 74 in a preferred embodiment, the spring opening 74 forms a pocket 78 on a front edge 74C of the spring opening 74. The pocket 78 bulges out of the front edge 74C in a semicircular fashion and at its apex includes a flap 78A that extends toward the back of the cage 70. Referring again to FIG. 6B, when the component 20 is in the final position, the free end 52B of the leaf spring 52 retracts through the spring opening 74. The flap 78A on the pocket 78, stops the free end 52B of the leaf spring 52 from extending beyond the height of the pocket 78, and the pocket 78 prevents the free end 52B of the leaf spring 52 from overlapping with the front edge 74C of the spring opening 74.

Referring again to FIGS. 2 and 5, the retainer clip 50 also includes a blocking belt loop 56, which is positioned at the front edge 58 on the outer surface 53 of the retainer clip 50. The belt loop 56 protrudes outward from the outer surface 53 of the retainer clip 50, and prevents the component 20 from being inserted past the final position within the cage 70 by engaging a finger 75 extending from the front face 71 of the cage 70.

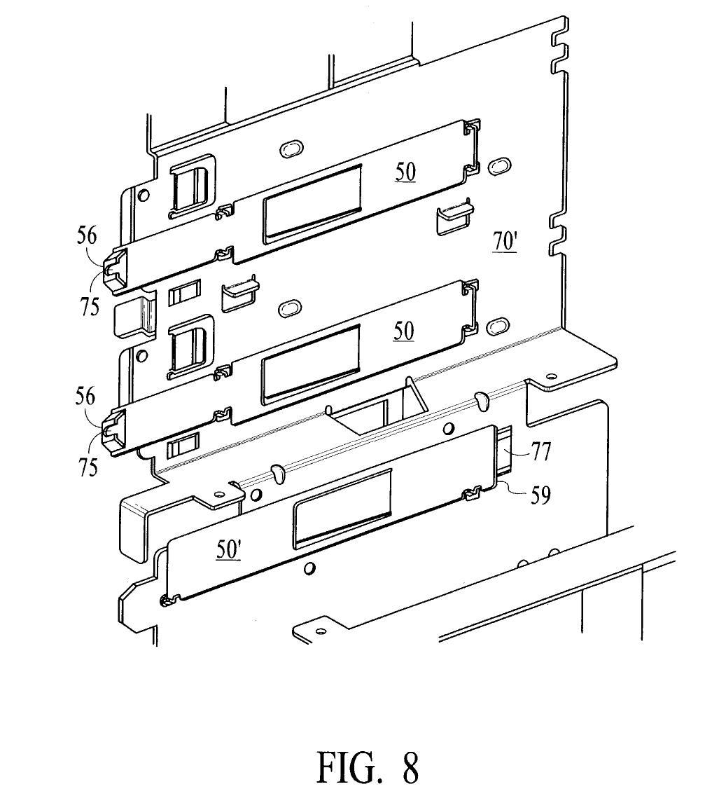

FIG. 8 illustrates the retainer clip 50 viewed from inside the cage 70′ according to the preferred embodiment of the present invention. As is shown, the belt loop 56 preferably slips over the finger 75. FIG. 8 also illustrates the retainer clip 50′ for the smaller device (FIG. 2B), which does not include a belt loop. In this embodiment, the cage 70′ includes a slight indentation 77, which engages a back edge 59 of the retainer clip 50.′ Note that the height of the indentation 77 is such that it does not make contact with the component itself, but only makes contact with the retainer clip 50.′

Thus, once the component 20 is placed in the final position and the leaf spring 52 retracts into the spring opening 74, the cooperation of the pocket 78, flap 78A and spring leaf 52 ensures that the component 20 cannot be moved in a direction toward the front face 71 of the cage 70. The cooperation of the belt loop 56 and finger 77, or the indentation 77 and back edge 59 of the retainer clip, ensures that the component 20 cannot be moved in a direction away from the front face 71. In addition, because the through holes 76 are aligned with the component's screw holes (not shown), the component can be further secured to the cage 70 with screws in the event that the leaf spring 52 becomes defective or extra security is needed.

In order to move the component 20 forward from the final position, the technician only needs to push the free end 52B of the leaf spring 52 toward the component 20 so that the free end 52B is beneath the front edge 74C of the spring opening 74. At this point, the free end 52B of the leaf spring 52 can slide into the cage 70 and the component 20 can be removed or moved through the front face 71 of the cage 70.

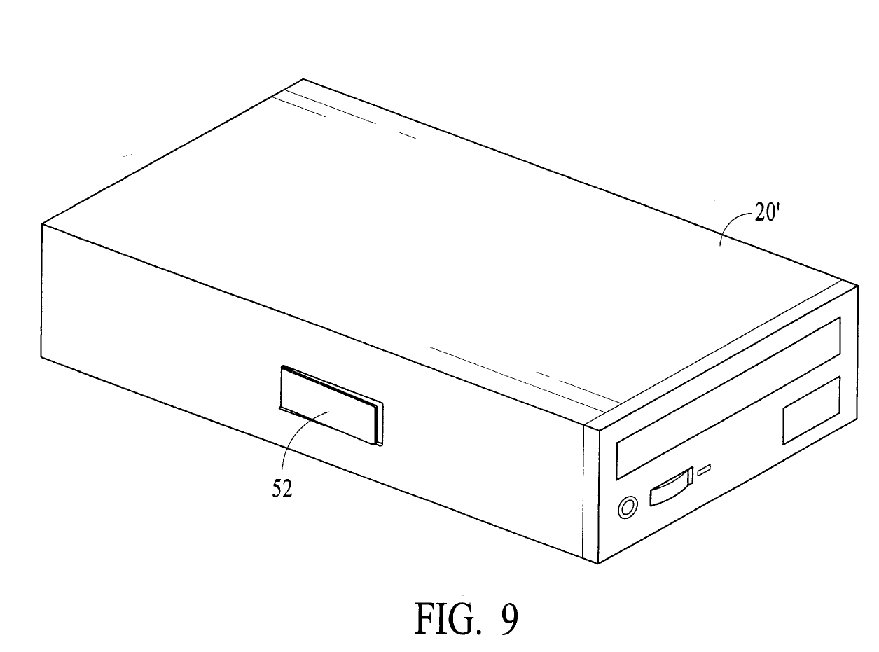

Although the present invention has been described in accordance with the embodiment shown, one of ordinary skill in the art will readily recognize that there could be variations to the embodiment and those variations would be within the spirit and scope of the present invention. For instance, in FIG. 9, a leaf spring 52 may be incorporated directly into the component housing 20′, thereby eliminating the need for attaching a retainer clip to the component. Accordingly, many modifications may be made by one of ordinary skill in the art without departing from the spirit and scope of the appended claims.

What is claimed is:

1. A system for securing a computer component in a cage of a computer system comprising:
a retainer clip for engaging a surface of the computer component, the retainer clip comprising a leaf spring, wherein the leaf spring engages the cage when the component is placed into the cage.

2. The system of claim 1, wherein the retainer clip comprises an inner surface and an outer surface, and wherein the retainer clip further comprises a plurality of tabs extending from the inner surface for coupling the retainer clip to the side surface of the component.

3. The system of claim 2, wherein the plurality of tabs are configured to fit through a corresponding plurality of screw holes in the side surface of the component.

4. The system of claim 2, wherein the component is a 5.25″ device and the retainer clip comprises four tabs.

5. The system of claim 2, wherein the component is a 3.5″ device and the retainer clip comprises two tabs.

6. The system of claim 1, wherein the retainer clip is sheet metal.

7. A system for securing a computer component in a computer system comprising:
a cage for receiving the computer component; and
a retainer clip comprising a leaf spring, the retainer clip being coupled to a surface of the component, wherein the leaf spring engages the cage when the component is placed into the cage.

8. The system of claim 7, wherein the cage comprises an opening through which the leaf spring of the retainer clip retracts when the component is placed in a final position within the cage.

9. The system of claim 8, wherein the opening comprises a front edge and a back edge, and wherein the cage further comprises a pocket at the front edge of the spring opening for latching the leaf spring when the component is placed in the final position.

10. The system of claim 9, wherein the pocket is a semicircular protrusion which further comprises a flap at the pocket's apex, wherein the flap prevents the leaf spring from retracting beyond a height of the pocket.

11. The system of claim 8, wherein the cage further comprises a finger extending from a front face of the cage and the retainer clip further comprises a belt loop protruding from a front edge of the retainer clip, whereby the belt loop slips over the finger when the component is in the final position.

12. The system of claim 8, wherein the cage further comprises an indentation for engaging a back edge of the retainer clip when the component is in the final position.

13. The system of claim 8, wherein the cage further comprises a plurality of through holes, wherein the plurality of through holes corresponds to a plurality of screw holes in the side surface of the component.

14. The system of claim 7, wherein the retainer clip comprises an inner surface and an outer surface, and wherein the retainer clip further comprises a plurality of tabs extending from the inner surface for coupling the retainer clip to the side surface of the component.

15. The system of claim 14, wherein the plurality of tabs are configured to fit through a corresponding plurality of screw holes in the side surface of the component.

16. A system for securing a component in a computer system comprising:
a retainer clip comprising a leaf spring, the retainer clip being coupled to a side surface of the component; and
a cage for receiving the computer component, wherein the cage comprises a spring opening through which the leaf spring of the retainer clip retracts when the component is placed in a final position within the cage.

17. The system of claim 16, wherein the spring opening comprises a front edge and a back edge, and wherein the cage further comprises a pocket at the front edge of the spring opening for latching the leaf spring when the component is placed in the final position.

18. The system of claim 17, wherein the pocket is a semicircular protrusion which further comprises a flap at the pocket's apex, wherein the flap prevents the leaf spring from retracting beyond a height of the pocket.

19. A system for securing a component in a computer system comprising:
a housing enclosing the component, wherein the housing comprises a leaf spring formed on a side surface thereof; and
a cage for receiving the computer component, wherein the cage comprises a spring opening through which the leaf spring retracts when the component is placed in a final position within the cage.

20. The system of claim 19, wherein the spring opening comprises a front edge and a back edge, and wherein the cage further comprises a pocket at the front edge of the spring opening for latching the leaf spring when the component is placed in the final position.

21. The system of claim 20, wherein the pocket is a semicircular protrusion which further comprises a flap at the pocket's apex, wherein the flap prevents the leaf spring from retracting beyond a height of the pocket.
